(19) United States
(12) Patent Application Publication
(10) Pub. No.: US 2016/0133677 A1
(43) Pub. Date: May 12, 2016

(54) ORGANIC LIGHT-EMITTING DEVICE AND ORGANIC DISPLAY DEVICE EACH INCLUDING LIGHT EMITTERS IN A TWO-DIMENSIONAL ARRANGEMENT ALONG A MAIN SURFACE OF A SUBSTRATE, THE LIGHT EMITTERS BEING DEFINED BY BANKS

(71) Applicant: JOLED INC., Tokyo (JP)

(72) Inventors: Tsuyoshi YAMAMOTO, Osaka (JP); Nobuto HOSONO, Tokyo (JP)

(73) Assignee: JOLED INC., Tokyo (JP)

(21) Appl. No.: 14/931,245

(22) Filed: Nov. 3, 2015

(30) Foreign Application Priority Data
Nov. 6, 2014 (JP) 2014-225771

(51) Int. Cl. H01L 27/32; H01L 51/50

(52) U.S. Cl. CPC H01L 27/3246; H01L 51/5012; H01L 2251/558; H01L 2251/303; H01L 2251/301

(57) ABSTRACT

An organic light-emitting device including a substrate, light emitters in a two-dimensional arrangement along a surface of the substrate, and banks that define the light emitters. The banks include elongated first banks and elongated second banks. The first banks and the second banks intersect. The first banks and the second banks include insulating material, and surfaces of the first banks and the second banks that face an organic functional layer of any of the light emitters contain fluorine. The first banks are above the second banks at each intersection between the first banks and the second banks. Fluorine concentration of the surface portion of each of the second banks is less than fluorine concentration of the surface portion of each of the first banks.

This application is based on an application No. 2014-225771 filed in Japan, the contents of which are hereby incorporated by reference.

### BACKGROUND OF THE DISCLOSURE

(1) Technical Field

The present disclosure relates to organic light-emitting devices and organic display devices that comprise light emitters in a two-dimensional arrangement along a main surface of a substrate, the light emitters being defined by banks, and in particular to configuration of the banks that define the light emitters.

(2) Description of Related Art

In recent years, organic light-emitting devices such as organic electroluminescence (EL) panels, organic EL lighting, etc., are being developed, as disclosed in JP 2002-75640. Configuration of an organic EL panel pertaining to conventional technology is described below with reference to FIG. 9A.

As illustrated in FIG. 9A, an organic EL panel pertaining to conventional technology comprises a TFT layer 901 and an insulating layer 902 layered in this order on a main surface (the main surface at an upper side in a Z-axis direction) of a substrate 900. An anode 903 and a hole injection layer 904 are layered in this order on the insulating layer 902 as a sub-pixel unit of a light-emitter. A second bank 915 that extends in an X-axis direction is formed on the insulating layer 902 in a gap portion that includes edges of the anode 903 and the hole injection layer 904 in a Y-axis direction. Further, also on the insulating layer 902 and perpendicular to the second bank 915, a first bank 905 is formed extending in the Y-axis direction.

Organic functional layers such as a hole transport layer 906, an organic light-emitting layer 907, an electron transport layer 908, etc., are formed and layered in a groove portion between adjacent ones of the first bank 905. A cathode 909 and a sealing layer 910 are formed and layered in this order on the electron transport layer 908 and covering a top surface portion of the first bank 905.

Although not illustrated in FIG. 9A, a resin layer and a color filter panel are formed and layered in this order on the sealing layer 910.

However, the inventors ascertained that, according to the organic light-emitting device pertaining to conventional technology, defective formation may occur of the organic functional layers comprising the hole transport layer 906, the organic light-emitting layer 907, etc., on the second bank 915. Specifically, as illustrated in FIG. 9B, it may occur that the hole transport layer 906 is not formed over a portion of a surface 915f of the second bank 915. Further, although not illustrated, the organic light-emitting layer 907 may also be similarly defectively formed.

This defective formation over the second bank 915 may lead to defective layer thickness and layer shape of organic functional layers (the hole transport layer 906, the organic light-emitting layer 907, etc.) of light emitters either side of the defective formation.

### SUMMARY OF THE DISCLOSURE

In view of the above, the present disclosure aims to provide an organic light-emitting device and organic display device that each suppress occurrence of defective formation of an organic functional layer in a gap region between adjacent light emitters and that each have high light emittance properties.

In order to achieve this aim, one aspect of the present disclosure is an organic light-emitting device comprising a substrate, light emitters, and banks.

The light emitters are in a two-dimensional arrangement along a surface of the substrate. The banks define the light emitters.

Each of the light emitters comprises the following layers.

A first electrode disposed above the substrate.

An organic functional layer disposed above the first electrode, the organic functional layer including at least an organic light-emitting layer.

A second electrode disposed on the organic functional layer.

Further, each of the light emitters is defined by first banks and second banks.

Further, the banks comprise the first banks and the second banks.

The first banks are each elongated in a first direction along the surface of the substrate and are arranged to be separated from each other in a second direction along the surface of the substrate that is perpendicular to the first direction.

The second banks are each elongated in the second direction and are arranged to be separated from each other in the first direction.

In the present aspect, the first banks and the second banks each comprise an insulating material, at least a surface portion of each of the first banks that faces the organic functional layer contains fluorine, at least a surface portion of each of the second banks that faces the organic functional layer contains fluorine, and the first banks are above the second banks at each intersection between the first banks and the second banks. Further, fluorine concentration of the surface portion of each of the second banks is less than 10% of fluorine concentration of the surface portion of each of the first banks.

According to the organic light-emitting device pertaining to the aspect above, fluorine concentration of the surface portion of each of the second banks is less than 10% of fluorine concentration of the surface portion of each of the first banks, and therefore occurrence of defective formation of an organic functional layer in a gap region between adjacent light emitters is suppressed, and a high light emittance property is achieved.

### BRIEF DESCRIPTION OF THE DRAWINGS

These and other objects, advantages, and features of the technology pertaining to the present disclosure will become apparent from the following description thereof taken in conjunction with the accompanying drawings, which illustrate at least one specific embodiment of the technology pertaining to the present disclosure.

FIG. 1 is a schematic block diagram illustrating a simplified configuration of an organic EL display device 1 pertaining to an embodiment.

FIG. 2 is a schematic plan view illustrating arrangement of sub-pixels 10a, 10b, 10c, 10c₁, 10c₂ in a display panel 10.

FIG. 3 is a schematic cross-sectional view illustrating a cross-section of A-A of FIG. 2.

FIG. 4 is a schematic cross-sectional view illustrating a cross-section of B-B of FIG. 2.

FIG. 5 is a schematic plan view illustrating arrangement of a first bank 105, a second bank 115, and an anode 104 in the display panel 10.

FIG. 6 is a schematic perspective view illustrating an extracted partial configuration of the display panel 10.

FIG. 7A is a schematic cross-sectional view illustrating a relationship between the second bank 115 and a hole transport layer 106 in the display panel 10 pertaining to an embodiment.

FIG. 7B is a schematic cross-sectional view illustrating a relationship between a second bank 965 and a hole transport layer 956 in a display panel pertaining to a comparative example.

FIG. 8 is a process schematic illustrating a process of manufacturing the display panel 10.

FIG. 9A is a schematic perspective view illustrating an extracted partial configuration of a display panel pertaining to conventional technology.

FIG. 9B is a schematic cross-sectional view illustrating an aspect of defective formation of a hole transport layer 906 as ascertained by the inventors.

### DESCRIPTION OF EMBODIMENT

### [Considerations]

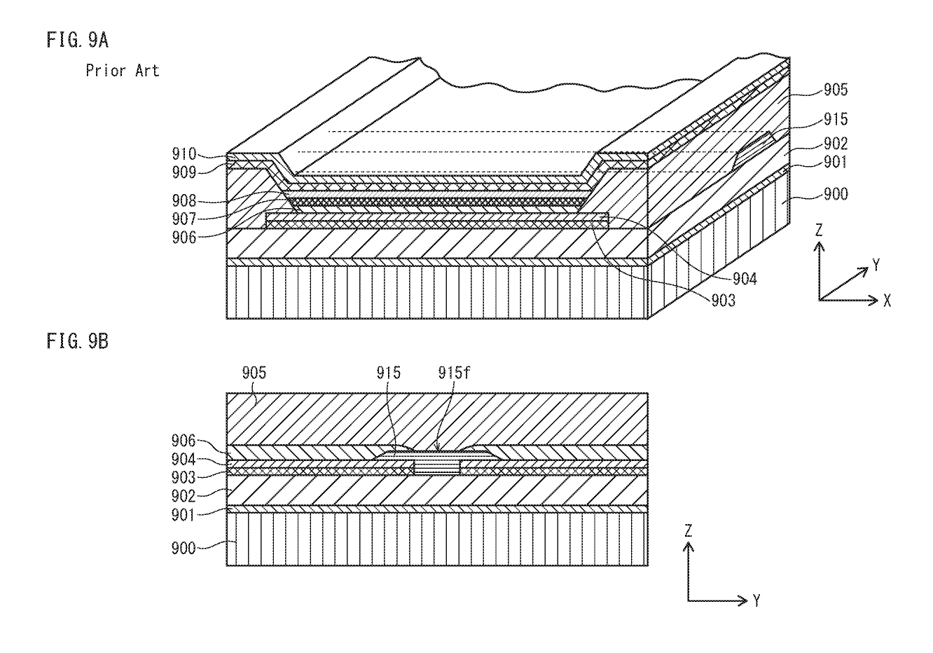

Items considered by the inventors regarding each aspect of the technology pertaining to the present disclosure are described with reference to FIG. 9B.

The second bank 915 is responsible for preventing short-circuiting of adjacent ones of the anode 903, and preventing electroluminescence at edge portions of the anode 903.

However, as illustrated in FIG. 9B, in an organic EL panel (organic light-emitting device) pertaining to conventional technology, a case may occur in which the hole transport layer (organic layer) 906 is not formed over a portion of the surface 915f of the second bank 915, which can be referred to as “non-wetting”. The inventors arrived at the conclusion that the relationship between a contact angle of a surface portion of the second bank 915 and a contact angle of a surface portion of the first bank 905 has a large influence as a cause of non-wetting. More specifically, the inventors found that the relationship between fluorine concentration at the surface portion of the second bank 915 and fluorine concentration at the surface portion of the first bank 905 is of importance.

### [Aspects of the Present Disclosure]

One aspect of the present disclosure is an organic light-emitting device comprising a substrate, light emitters, and banks.

The light emitters are in a two-dimensional arrangement along a surface of the substrate. The banks define the light emitters.

Each of the light emitters comprises the following layers.

A first electrode disposed above the substrate.

An organic functional layer disposed above the first electrode, the organic functional layer including at least an organic light-emitting layer.

A second electrode disposed on the organic functional layer.

Further, each of the light emitters is defined by first banks and second banks.

Further, the banks comprise the first banks and the second banks.

The first banks are each elongated in a first direction along the surface of the substrate and are arranged to be separated from each other in a second direction along the surface of the substrate that is perpendicular to the first direction.

The second banks are each elongated in the second direction and are arranged to be separated from each other in the first direction.

In the present aspect, the first banks and the second banks each comprise an insulating material, at least a surface portion of each of the first banks that faces the organic functional layer contains fluorine, at least a surface portion of each of the second banks that faces the organic functional layer contains fluorine, and the first banks are above the second banks at each intersection between the first banks and the second banks. Further, fluorine concentration of the surface portion of each of the second banks is less than 10% of fluorine concentration of the surface portion of each of the first banks.

According to the organic light-emitting device pertaining to this aspect, fluorine concentration of the surface portion of each of the second banks is less than 10% of fluorine concentration of the surface portion of each of the first banks, and therefore occurrence of defective formation of an organic functional layer in a gap region between adjacent light emitters is suppressed, and a high light emittance property is achieved.

Further, according to the organic light-emitting device pertaining to another aspect of the present disclosure, the fluorine concentration of the surface portion of each of the second banks is less than 7.5% of the fluorine concentration of the surface portion of each of the first banks. Thus, fluorine concentration of the surface portion of each of the second banks is less than 7.5% of fluorine concentration of the surface portion of each of the first banks, and therefore occurrence of defective formation of an organic functional layer in a gap region between adjacent light emitters is further suppressed, and a higher light emittance property is achieved.

Further, according to the organic light-emitting device pertaining to another aspect of the present disclosure, in each of the light emitters, a charge injection layer is disposed between the first electrode and the organic functional layer, the charge injection layer being in contact with the organic functional layer. Further, the fluorine concentration of the surface portion of each of the second banks is less than 400% of fluorine concentration of a surface portion of the charge injection layer that faces the organic functional layer. In other words, a ratio of fluorine concentration of the surface portion of the charge injection layer to fluorine concentration of the surface portion of each of the second banks is greater than ¼.

Thus, by defining a relationship between fluorine concentration of the surface portion of the charge injection layer and fluorine concentration of the surface portion of each of the second banks, occurrence of areas not covered by ink when forming a continuous organic layer on the charge injection layer and the second banks can be prevented, and differences in formation of the organic layer relative to the charge injection layer and the second banks can be suppressed. Thus, this aspect excels in ensuring uniformity of layer formation, including layer thickness, of the organic layer in adjacent ones of the light emitters.

Further, according to the organic light-emitting device pertaining to another aspect of the present disclosure, each of the second banks comprises an organic material, and an inorganic layer is disposed between at least a portion of each shared boundary between the second banks, the organic functional layer, and the first banks, the inorganic layer being comprised of an inorganic material and in contact with each of the second banks, the organic functional layer, and each of the first banks. In other words, at least a portion of the surface portion of each of the second banks is covered by the inorganic layer. Thus, when a configuration in which at least a portion of the surface portion of each of the second banks is covered by the inorganic layer, fluorine in each of the second banks is prevented from diffusing into the surface portion of a lower layer exposed between adjacent ones of the second banks (the first electrode or charge injection layer) when the first banks are formed. According to this configuration, when forming the organic functional layer, uncovered areas of the surface portion of the lower layer can be prevented, and formation of the organic functional layer on the lower layer can be further improved.

Further, according to the organic light-emitting device pertaining to another aspect of the present disclosure, the inorganic layer comprises silicon oxide, silicon nitride, or silicon oxynitride.

Further, according to the organic light-emitting device pertaining to another aspect of the present disclosure, thickness of each of the second banks is 0.80 μm or less. Thus, by defining the thickness of each of the second banks to be 0.80 μm or less, occurrence of areas uncovered by ink during formation of the organic functional layer can be effectively suppressed.

Further, according to the organic light-emitting device pertaining to another aspect of the present disclosure, height of each of the first banks is from 0.50 μm to 1.1 μm higher than each of the second banks. Thus, high thickness uniformity of the organic functional layer can be ensured.

Further, according to the organic light-emitting device pertaining to another aspect of the present disclosure, the first electrode, at a portion of a peripheral region of each respective one of the light emitters, has a flat region along a plane parallel to the surface of the substrate, each of the second banks is above the flat region of corresponding ones of the first electrode, and the thickness of each of the second banks is defined as thickness of a portion of each of the second banks above the flat region of corresponding ones of the first electrode. Thus, a region that defines thickness of each of the second banks is clarified.

Further, an organic display device pertaining to one aspect of the present disclosure comprises a display panel and control/drive circuitry connected to the display panel, in which the device structure of the organic light-emitting device pertaining to any one of the above aspects can be adopted as the display panel. Thus, according to the organic display device pertaining to this aspect, the effects achieved by the organic light-emitting device pertaining to the any one of the above aspects can be achieved.

### [Embodiment]

With reference to the drawings, configuration of the organic EL display device pertaining to an embodiment is described below.

### 1. Schematic Configuration of Device

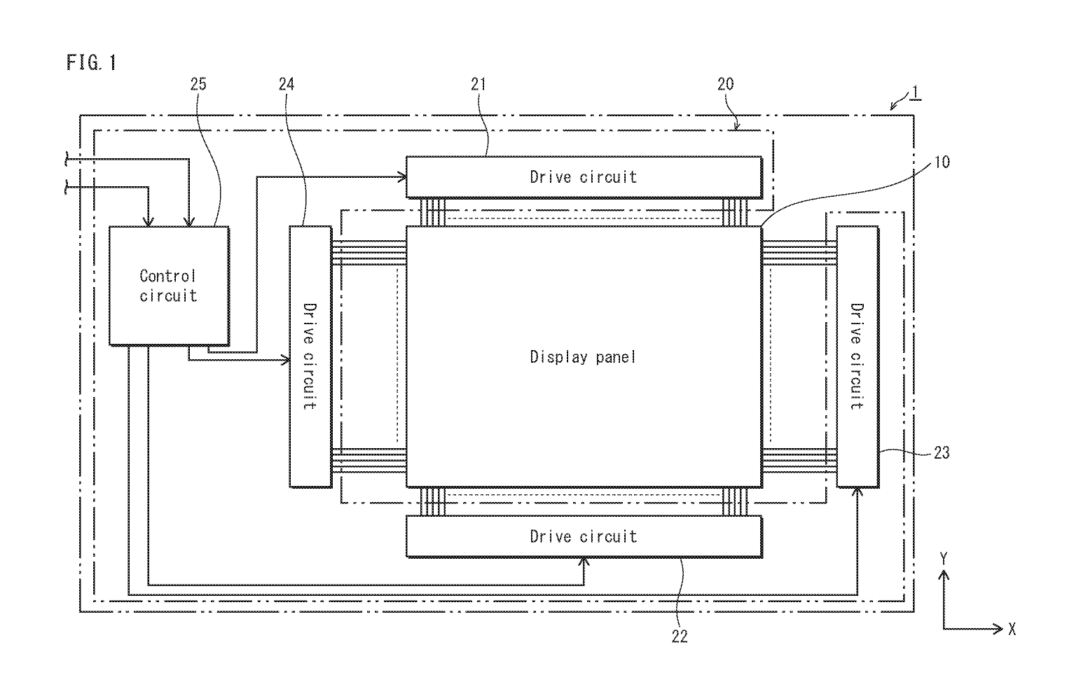

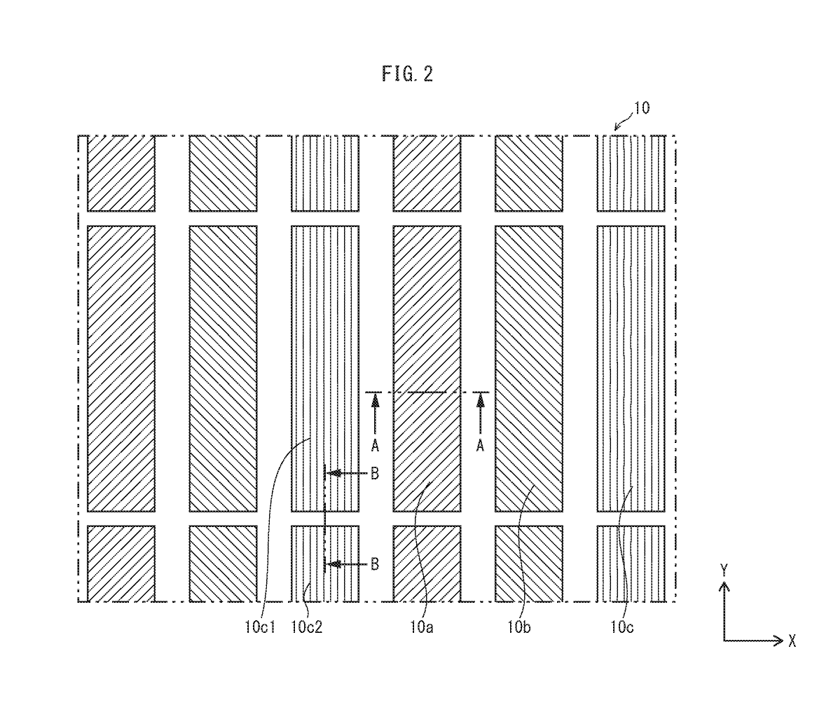

Schematic configuration of an organic EL display device 1 pertaining to the present embodiment is described with reference to FIG. 1 and FIG. 2. In the present embodiment, the organic EL display device 1 is described as an example of an organic display device.

As illustrated in FIG. 1, the organic EL display device pertaining to the present embodiment comprises a display panel 10 and drive/control circuitry 20 connected to the display panel 10. The display panel 10 is a type of organic light-emitting device, and is an organic EL panel that utilizes electroluminescence of organic material.

As illustrated in FIG. 2, in the display panel 10, a plurality of sub-pixels 10a, 10b, 10b, 10c₁, 10c₂, . . . are arranged in two dimensions in an X-axis direction and a Y-axis direction. In the present embodiment, as an example, sub-pixel 10a is a light emitter that emits red (R) light, sub-pixel 10b is a light emitter that emits green (G) light, and sub-pixels 10b, 10c₁, 10c₂ are light emitters that emit blue (B) light. One pixel comprises a combination of three sub-pixels 10a, 10b, 10c that are adjacent in the X-axis direction.

Returning to FIG. 1, the drive/control circuitry 20 of the organic EL display device 1 comprises four drive circuits 21, 22, 23, 24 and one control circuit 25. The relative positions of the display panel 10 and the drive/control circuitry 20 of the organic EL display device 1 are not limited to the example illustrated in FIG. 1.

Further, configuration of a pixel is not limited to the example of a combination of sub-pixels 10a, 10b, 10c illustrated in FIG. 2, and a pixel may comprise a combination of four or more sub-pixels.

2. Configuration of display panel 10

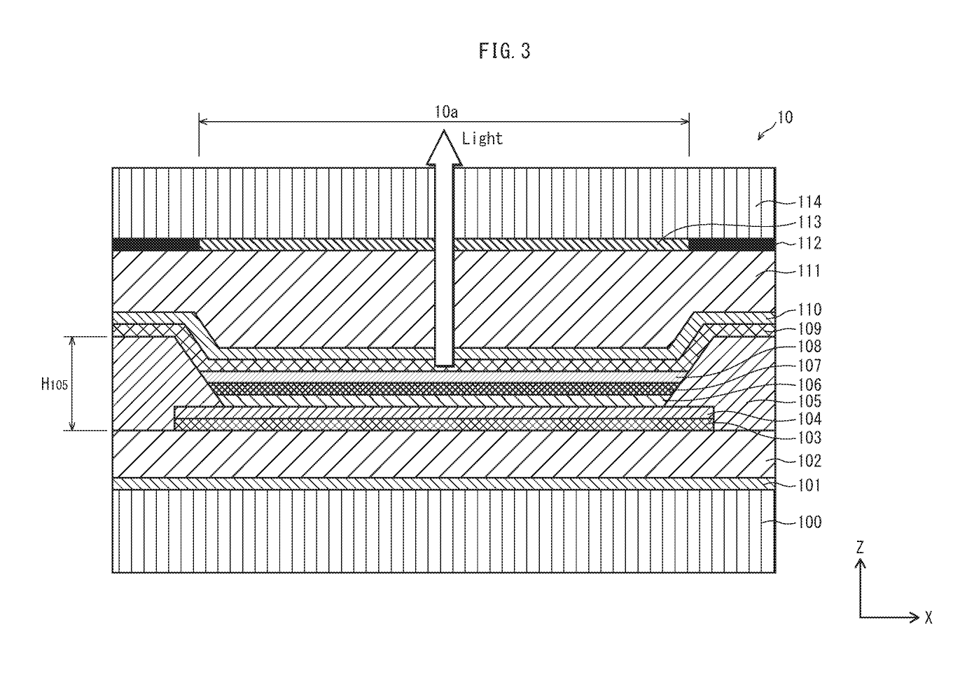

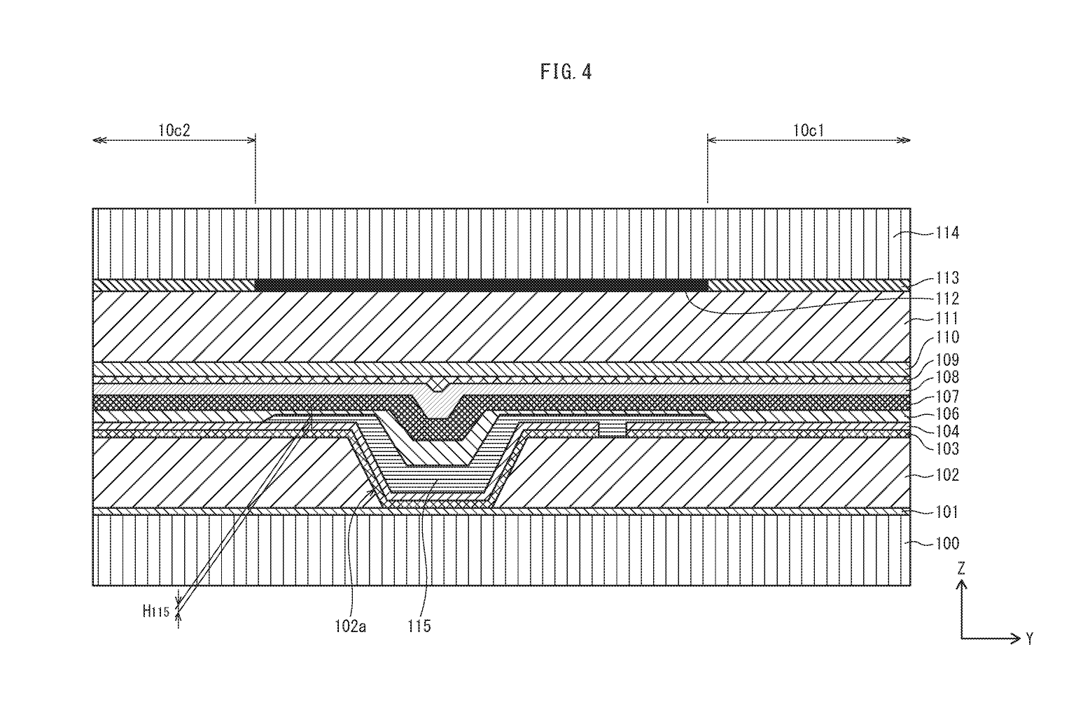

In the present embodiment, configuration of the display panel 10 as one example of an organic light-emitting device is described with reference to FIG. 3 and FIG. 4.

As illustrated in FIG. 3, the display panel 10 comprises a substrate 100, a substrate 114, and a plurality of layers 101 to 113 between the substrate 100 and the substrate 114.

First, the substrate 100 is disposed at a lower side of a Z-axis direction and a thin film transistor (TFT) layer 101 is formed on a main surface of the substrate 100. Although details are omitted from FIG. 3, the TFT layer 101 has a known configuration in which one, two, or more transistor elements are formed for each sub-pixel of the sub-pixels 10a, 10b, 10b, 10c₁, 10c₂.

On the TFT layer 101, an insulating layer 102, an anode 103, and a hole injection layer 104 are formed and layered in this order, upwards in the Z-axis direction. The anode 103 and the hole injection layer 104 are formed for each of the sub-pixels 10a, 10b, 10b, 10c₁, 10c₂.

As illustrated in FIG. 4, a contact hole 102a is provided in the insulating layer 102 in a non-light-emitting region between adjacent ones of the sub-pixels 10c₁, 10c₂ in the Y-axis direction. The contact hole 102a is for connecting the anode 103 and a source or drain of the TFT layer 101 for a sub-pixel (in FIG. 4, sub-pixel 10c₂). The anode 103 and upper electrode (electrode connected to source or drain) of the TFT layer 101 are in contact with each other at a bottom portion of the contact hole 102a.

Returning to FIG. 3, first banks 105 are formed on the insulating layer 102 and covering both edges of the hole injection layer 104 in an X-axis direction. The first banks 105 each extend in a direction perpendicular to the plane of the cross-section (the Y-axis direction), and define the sub-pixels 10a, 10b, 10b, 10c₁, 10c₂ in the X-axis direction.

As illustrated in FIG. 4, in the non-light-emitting region between adjacent ones of the sub-pixels 10c₁, 10c₂ in the Y-axis direction, one of second banks 115 is formed so as to cover both edges of the anode 103 and the hole injection layer 104 in the Y-axis direction. As illustrated in FIG. 4, a portion of the one of the second banks 115 is recessed into the contact hole 102a.

Returning again to FIG. 3, in an opening defined on both sides in the X-axis direction by the first banks 105, a hole transport layer 106, an organic light-emitting layer 107, and an electron transport layer 108 are formed and layered in this order, upwards in the Z-axis direction. In the present embodiment, the hole transport layer 106, the organic light-emitting layer 107, and the electron transport layer are formed as an organic functional layer that is continuous in the Y-axis direction across the second banks 115, as illustrated in FIG. 4.

A first thin layer (for example, 4 nm) and a second thin layer (for example, 1 nm) may be interposed between the organic light-emitting layer 107 and the electron transport layer 108. The first thin layer comprises a compound of fluorine and an alkali metal or alkaline earth metal (for example, NaF). The second thin layer comprises an alkali metal or alkaline earth metal that has a function of breaking bonds between the fluorine and the alkali metal or alkaline earth metal in the first thin layer (for example, Ba).

A cathode 109 and a sealing layer 110 are formed and layered in this order upwards in the Z-axis direction and covering a top faces of the first banks 105. The cathode 109 and the sealing layer 110 are formed to be continuous across all pixel regions of the display panel 10.

A color filter layer 113 and a black matrix layer 112 are formed on a main surface of the substrate 114, the main surface of the substrate 114 being a lower-side surface of the substrate 114 in the Z-axis direction and the substrate 114 being at an upper end in the Z-axis direction. A resin layer 111 is interposed between the sealing layer 110 and the color filter layer 113/black matrix layer 112. The resin layer 111 is in close contact with the sealing layer 110 and the color filter layer 113/black matrix layer 112 without any gaps therebetween.

Other sub-pixels 10b, 10b, 10c₁, 10c₂ in the display panel 10 also have the same configuration as described above.

The display panel 10 pertaining to the present embodiment, as illustrated in FIG. 3, is a top-emission type of panel in which light is transmitted through and emitted from the substrate 114.

### 3. Material of Display Panel 10

### (1) Substrate 100

The substrate 100 is formed by using, for example: a glass substrate; a silica glass substrate; a silicon substrate; a metal substrate such as molybdenum sulfide, copper, zinc, aluminium, stainless, magnesium, iron, nickel, gold, silver, etc.; a semiconductor substrate such as a gallium arsenide base; or a plastic substrate.

As a plastic substrate, a thermoplastic resin or thermosetting resin may be used. For example, the plastic substrate may be a layered substrate in which one or more of following is used in one or more layers: a polyolefin such as polyethylene, polypropylene, ethylene-propylene copolymer, ethylene-vinyl acetate copolymer (EVA), etc., cyclic polyolefin, modified polyolefin, polyvinyl chloride, polyvinylidene chloride, polystyrene, polyamide, polyimide (PI), polyamide-imide, polycarbonate, poly-(4-methyl-1-pentene), ionomer, acrylic resin, polymethyl methacrylate, acryl-styrene copolymer (AS resin), butadiene-styrene copolymer, ethylene vinyl alcohol (EVOH) copolymer, polyethelene terephthalate (PET), polybutylene terephthalate, polyethylene naphthalate (PEN), polyester such as polycyclohexylenedimethylene terephthalate (PCT), polyether, polyether ketone, polyether sulfone (PES), polyetherimide, polyacetal, polyphenylene oxide, modified polyphenylene oxide, polyarylate, aromatic polyester (liquid crystal polymer), polytetrafluoroethylene, polyvinylidene fluoride, another fluorine-based resin, various thermoplastic elastomers such as styrene-based, polyolefin-based, polyvinyl chloride-based, polyurethane-based, or fluororubber-based thermoplastic elastomers, epoxy resin, phenolic resin, urea resin, melamine resin, unsaturated polyester, silicon resin, polyurethane, etc., or a copolymer, blend, polymer alloy, etc., that primarily comprises one of the above.

### (2) TFT Layer 101

The TFT layer 101 comprises at least one transistor element per sub-pixel. Each transistor element comprises three electrodes (gate, source, and drain), a semiconductor layer, a passivation layer, etc.

### (3) Insulating Layer 102

The insulating layer 102 is, for example, formed using an organic compound such as polyimide, polyamide, or acrylic resin material. Here, the insulating layer 102 preferably has organic solvent resistance.

Further, the insulating layer 102 undergoes etching processing, baking processing, etc. during manufacture, and therefore forming the insulating layer 102 by using a material that has a high resistance to deformation, deterioration, etc., during these processes is preferable.

### (4) Anode 103

The anode 103 comprises a metal material including silver (Ag) or aluminium (Al). In the case of the display panel 10 pertaining to the present embodiment, which is top-emission, a surface portion of the anode 103 preferably has high reflectivity.

The anode 103 need not be only a single layer comprising the metal material as described above, and may be a layered body comprising a metal layer and a light-transmissive conductive layer. As a material of the light-transmissive conductive layer, indium tin oxide (ITO) or indium zinc oxide (IZO) may be used.

### (5) Hole Injection Layer 104

The hole injection layer 104 is a layer comprising an oxide of silver (Ag), molybdenum (Mo), chromium (Cr), vanadium (V), tungsten (W), nickel (Ni), or iridium (Ir), or a semiconducting polymer material such as poly(3,4-ethylenedioxythiophene)polystyrene sulfonate (PEDOT:PSS).

When using a metal oxide as a material of the hole injection layer 104, compared to when using a semiconducting polymer material such as PEDOT:PSS, the hole injection layer 104 more stably assists in generating holes, injecting holes to the organic light-emitting layer 107, and has a larger work function.

When the hole injection layer 104 comprises a transition metal oxide, a plurality of oxidation numbers can be achieved and therefore a plurality of energy levels can be obtained. As a result, hole injection becomes easier and drive voltage can be reduced. In particular, using tungsten oxide (WO_{X}) in the hole injection layer 104 is preferable from the point of view of stably injecting holes and assisting in hole generation.

### (6) First Banks 105

The first banks 105 are formed using an organic material such as resin, and have an insulating property. As an example of organic material used to form the first banks 105, acrylic resin, polyimide resin, or novalac-type phenolic resin may be used. In order to impart liquid repellency to a surface of each of the first banks 105, the surface may be fluorine-treated.

Further, structure of each of the first banks 105 is not limited to the single layer structure illustrated in FIG. 3 and FIG. 4, and may be a multi-layer structure comprising two or more layers. In this case, each layer may be the material described above, or inorganic material and organic material may be used for each layer.

### (7) Second Banks 115

The second banks 115 can be formed using, for example, organic insulating material. As a specific example of organic insulating material, acrylic resin, polyimide resin, siloxane resin or phenolic resin may be used.

As a material of the second banks 115, an inorganic insulating material such as silicon oxide, silicon nitride, or silicon oxynitride may be used.

### (8) Hole Transport Layer 106

The hole transport layer 106 is formed using a polymer compound having no hydrophilic group. For example, a polymer compound having no hydrophilic group may be used such as polyfluorene, a polyfluorene derivative, polyarylamine, or a polyarylamine derivative.

### (9) Organic Light-Emitting Layer 107

The organic light-emitting layer 107 has a function of emitting light when an excited state is generated by recombination of holes and electrons injected thereto. Material used in formation of the organic light-emitting layer 107 is a light-emitting organic material capable of layer formation by using a wet printing method such as an inkjet method.

Specifically, for example, the organic light-emitting layer is preferably formed by a fluorescent material such as an oxinoid compound, perylene compound, coumarin compound, azacoumarin compound, oxazole compound, oxadiazole compound, perinone compound, pyrrolo-pyrrole compound, naphthalene compound, anthracene compound, fluorene compound, fluoranthene compound, tetracene compound, pyrene compound, coronene compound, quinolone compound and azaquinolone compound, pyrazoline derivative and pyrazolone derivative, rhodamine compound, chrysene compound, phenanthrene compound, cyclopentadiene compound, stilbene compound, diphenylquinone compound, styryl compound, butadiene compound, dicyanomethylene pyran compound, dicyanomethylene thiopyran compound, fluorescein compound, pyrylium compound, thiapyrylium compound, selenapyrylium compound, telluropyrylium compound, aromatic aldadiene compound, oligophenylene compound, thioxanthene compound, cyanine compound, acridine compound, metal complex of an 8-hydroxyquinoline compound, metal complex of a 2-bipyridine compound, complex of a Schiff base and a group III metal, metal complex of oxine, or rare earth complex, as disclosed in JP H5-163488.

### (10) Electron Transport Layer 108

The electron transport layer 108 has a function of transporting electrons injected from the cathode 109 to the organic light-emitting layer 107 and, for example, is formed using oxydiazole derivative (OXD), triazole derivative (TAZ), or phenanthroline derivate (BCP, Bphen).

As the electron transport layer 108, a doped layer of an alkali metal or alkaline earth metal (for example, Ba) may be used instead of the organic material described above.

### (11) Cathode 109

The cathode 109 is formed by using, for example, indium tin oxide (ITO) or indium zinc oxide (IZO). When the display panel 10 is top-emission, as in the present embodiment, the cathode 109 is necessarily formed from a light-transmissive material. The light-transmissive material preferably has light transmittance of at least 80%.

Further, as a material of the cathode 109, silver (Ag), manganese silver (MgAg), or a layered body thereof may be used. A cavity design may also be used to improve light extraction efficiency.

(12) Sealing layer 110

The sealing layer 110 has a function of suppressing exposure of an organic layer such as the organic light-emitting layer 106 to water and air. The sealing layer 110 is formed using, for example, a material such as silicon nitride (SiN) or silicon oxynitride (SiON). Further, a sealing resin layer comprising a resin material such as acrylic resin or silicone resin may be provided on a layer formed using the material such as silicon nitride (SiN) or silicon oxynitride (SiON).

Further, the sealing layer 110 may be a layered body comprising layers of silicon oxide (SiO₂), silicon nitride (SiN), and silicon oxide (SiO₂) in this order.

When the display panel 10 is top-emission, as in the present embodiment, the cathode 110 is necessarily formed from a light-transmissive material.

### (13) Resin Layer 111

The resin layer 111 is formed from a light-transmissive resin material such as an epoxy resin material. Other materials such as silicone resin may be used as a material of the resin layer 111.

### (14) Black Matrix Layer 112

The black matrix layer 112 comprises, for example, an ultraviolet curing resin that includes black pigment having excellent light absorption and light-shielding properties. Specifically, an example of an ultraviolet curing resin is acrylic resin.

### (15) Color Filter Layer 113

The color filter layer 113 comprises a known material that can selectively transmit visible light of red (R), green (G), and blue (B) wavelengths. For example, the color filter layer 113 may be acrylic resin-based.

### (16) Substrate 114

The substrate 114 is formed by using, for example: a glass substrate; a silica glass substrate; a silicon substrate; a metal substrate such as molybdenum sulfide, copper, zinc, aluminium, stainless, magnesium, iron, nickel, gold, silver, etc.; a semiconductor substrate such as a gallium arsenide base; or a plastic substrate, as per the substrate 100 described above. The substrate 114, when implemented as a plastic substrate, may be a thermoplastic resin or thermosetting resin.

### 4. Form of First Banks 105 and Second Banks 115

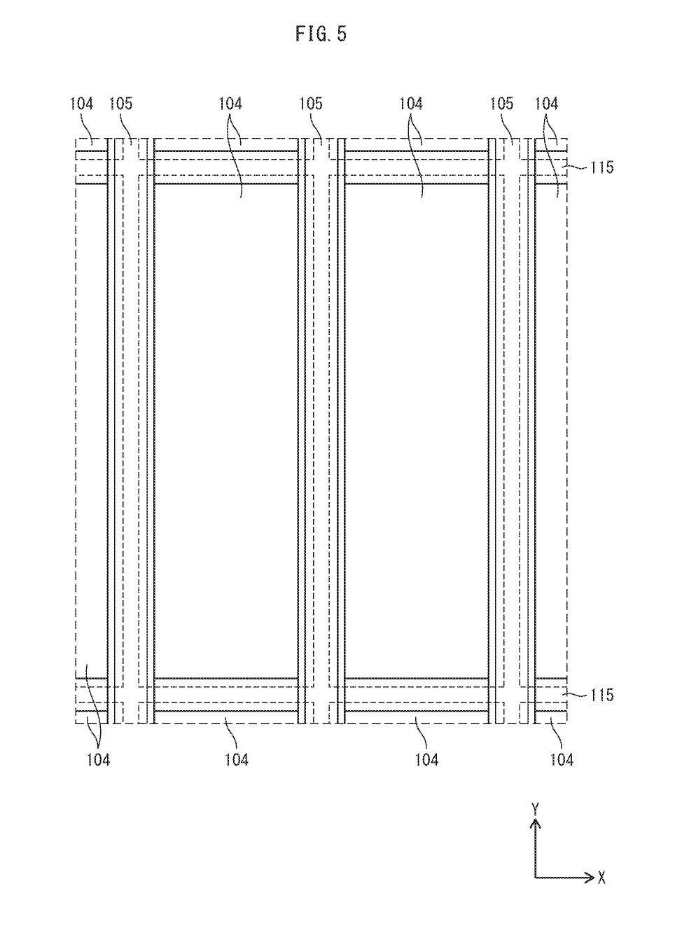

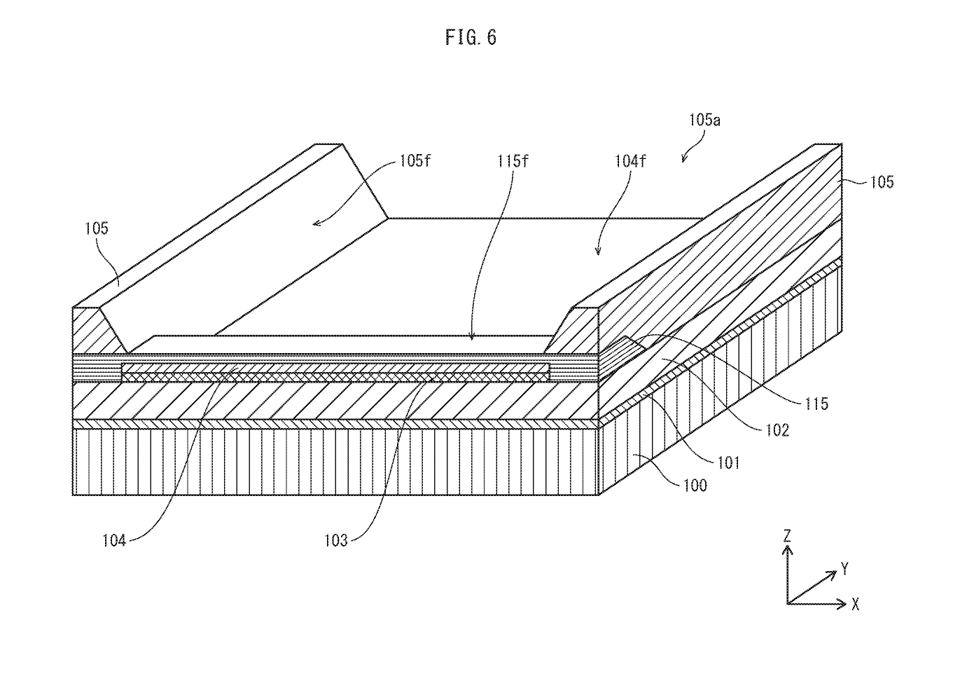

Form of the first banks 105 and the second banks 115 is described with reference to FIG. 5 and FIG. 6.

As illustrated in FIG. 5, the first banks 105 are formed to each extend in the Y-axis direction and to be separated from each other in the X-axis direction.

On the other hand, the second banks 115 are formed to each extend in the X-axis direction and to be separated from each other in the Y-axis direction. As illustrated in FIG. 6, the second banks 115 are under the first banks 105 at each intersection between the second banks 115 and the first banks 105. In other words, the first banks 105 are layered on the second banks 115.

Returning to FIG. 5, the first banks 105 are interposed in gaps in the X-axis direction between adjacent ones of the hole injection layer 104 and the anode 103 below the hole injection layer 104 (not illustrated in FIG. 5), covering each edge portion of the hole injection layer 104. The second banks 115 are interposed in gaps in the Y-axis direction between adjacent ones of the hole injection layer 104 and the anode 103 below the hole injection layer 104 (not illustrated in FIG. 5), covering each edge portion of the hole injection layer 104.

As illustrated in FIG. 5, the first banks 105 and the second banks 115 form a grid, and each space within the grid corresponds to a sub-pixel.

Each of the first banks 105 and each of the second banks 115 comprise an insulating organic material, as described above, and, as illustrated in FIG. 6, at least each surface portion 105f and each surface portion 115f contains fluorine. Further, in the present embodiment, a surface portion 104f of the hole injection layer 104 also contains a slight presence of fluorine.

Here, when fluorine concentration of the surface portion 105f of each of the first banks 105 is Df₁₀₅ and fluorine concentration of the surface portion 115f of each of the second banks 115 is Df₁₁₅, the following relationship is satisfied in the present embodiment.

Df₁₁₅<Df₁₀₅×0.10 [Math 1]

Further, when concentration of fluorine present in the surface portion 104f of the hole injection layer 104 is Df₁₀₄, the following relationship is satisfied.

Df₁₁₅/Df₁₀₄<4.00 [Math 2]

Although not illustrated in FIG. 6, the opening 105a defined by adjacent ones of the first banks 105 is filled with the hole transport layer 106, the organic light-emitting layer 107, and the electron transport layer 108. This is illustrated in FIG. 3 and FIG. 4. Here, the organic functional layer comprising the hole transport layer 106, the organic light-emitting layer 107, and the electron transport layer 108 is continuous, without interruption, in the Y-axis direction across the second banks 115.

### 5. Fluorine Concentration Df₁₁₅ of the Surface Portion 115f of Each of the Second Banks 115 and Quality of Formation of Organic Layer

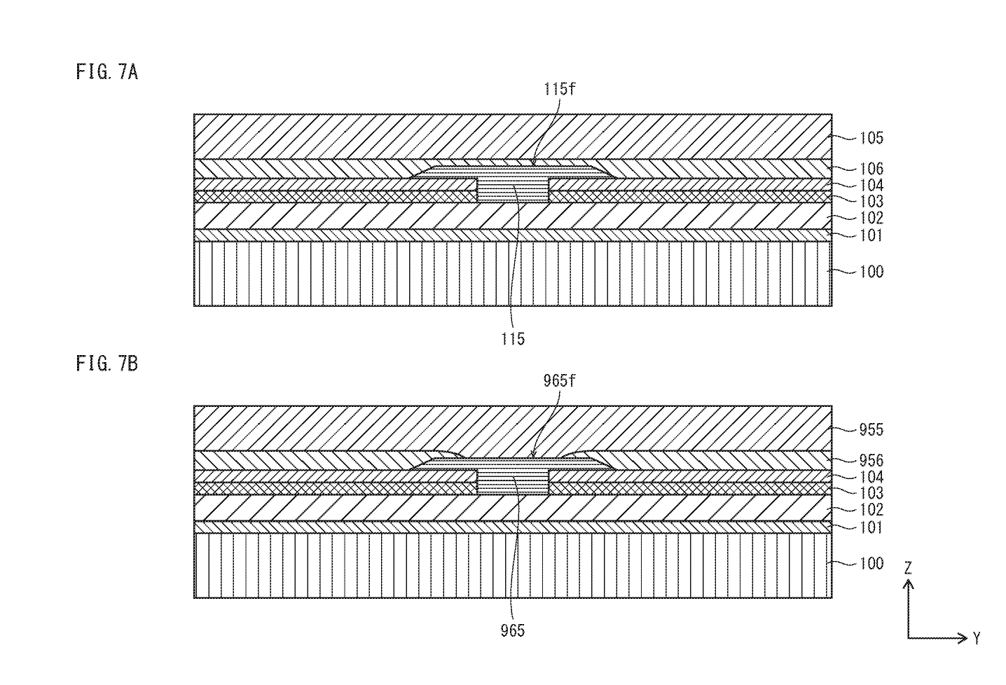

Fluorine concentration Df₁₁₅ of the surface portion 115f of each of the second banks 115 and quality of formation of an organic layer (the hole transport layer 106) is described below with reference to FIG. 7A and FIG. 7B. FIG. 7A illustrates the present embodiment and FIG. 7B illustrates a comparative example.

As illustrated in FIG. 7A, according to the present embodiment, the fluorine concentration Df₁₁₅ of the surface portion 115f of each of the second banks 115 is defined as described above (Math 1), and therefore the organic layer (hole transport layer 106) is also formed in good condition, without interruption, above (in the Z-axis direction) the second banks 115. In other words, during manufacture, a state in which ink for the hole transport layer 106 does not cover the surface portion 115f of each of the second banks 115 does not occur.

On the other hand, as illustrated in FIG. 7B, according to the comparative example, when Df₉₅₅ is a fluorine concentration of a surface portion of each of first banks 955 and Df₉₆₅ is a fluorine concentration of a surface portion 965f of each of second banks 965, Df₉₅₅ and Df₉₆₅ satisfy the following relationship.

Df₉₆₅≧Df₉₅₅×0.10 [Math 3]

According to the comparative example that satisfies the relationship of (Math 3), as illustrated in FIG. 7B, an organic layer (hole transport layer 956) may be interrupted above (in the Z-axis direction) the second banks 965. In other words, during manufacture, a state in which ink for the hole transport layer 956 does not cover the surface portion of each of the second banks 965 may occur.

Measurement results of the fluorine concentration Df₁₀₅ of the surface portion 105f of each of the first banks 105 and the fluorine concentration Df₁₁₅ of the surface portion 115f of each of the second banks 115 according to the present embodiment are shown in the following table.

TABLE 1

| | Df₁₁₅ | Df₁₀₅ | Df₁₁₅/Df₁₀₅ |
|---|---|---|---|
| Location 1 | 1648 | 24034 | 0.0686 |
| Location 2 | 2340 | 31658 | 0.0739 |

The results shown in (Table 1) were measured using the devices and methods below.

Time-of-flight secondary ion mass spectrometry (TOS-SIMS) measurement conditions.

Equipment: TRIFT™ 2 (ULVAC-PHI, Inc.)

Primary ion: Ga⁺, 18 kV

Analysis area: 150 μm×150 μm

Neutralizing gun: Flood gun on

Measurement results of the fluorine concentration Df₁₁₅ of the surface portion 115f of each of the second banks 115 and the fluorine concentration Df₁₀₄ in a surface portion 104f of the hole injection layer 104 according to the present embodiment are shown in the following table. Measurement equipment and method were as described above.

TABLE 2

| | Df₁₁₅ | Df₁₀₄ | Df₁₁₅/Df₁₀₄ |
|---|---|---|---|
| Location 1 | 1648 | 486 | 3.391 |
| Location 2 | 2340 | 848 | 2.759 |

As indicated in (Table 1), according to the present embodiment, the relationship described by (Math 1) is satisfied. According to the present embodiment, as indicated in (Table 1), the following relationship is satisfied.

Df₁₁₅<Df₁₀₅×0.075 [Math 4]

Further, as indicated in (Table 2), according to the present embodiment, the relationship described by (Math 2) is satisfied.

### 6. Height of First Banks 105 and Thickness of Second Banks 115

Relationship between height of the first banks 105, thickness of the second banks 115, and quality of formation of an organic layer (hole transport layer 106, organic light-emitting layer 107, etc.) is described with reference to FIG. 3 and FIG. 4.

As illustrated in FIG. 3, height, in the Z-axis direction, from an upper surface of the insulating layer 102 to a top surface of the first banks 105 is H₁₀₅.

Further, as illustrated in FIG. 4, thickness of the second banks 115 is H₁₁₅. As illustrated in FIG. 4, the thickness H₁₁₅ of the second banks 115 is thickness at a flat region of an edge region of the second banks 115 on a top surface of the hole injection layer 104 (a flat region parallel to a top surface of the substrate 100).

### (i) Height H₁₀₅ of the First Banks 105

The height H₁₀₅ of the first banks 105 is preferably within a range that satisfies the following equation.

0.50 μm≦H₁₀₅≦1.1 μm [Math 5]

As illustrated in FIG. 6, the height H₁₀₅ of the first banks 105 is assumed to be higher than the thickness H₁₁₅ of the second banks 115.

The lower limit of the height H₁₀₅ (0.5 μm) was determined by the inventors to be a limit value for ensuring layer thickness uniformity of the first banks 105 during manufacture thereof. Specifically, when forming an organic layer for forming the first banks 105 by a roll coating method, it becomes difficult to ensure layer thickness uniformity at a thickness less than 0.50 μm.

On the other hand, when the upper limit of the height H₁₀₅ (1.1 μm) of the first banks 105 is exceeded, ensuring layer thickness uniformity of an organic layer (in particular the organic light-emitting layer 107) becomes difficult. As determined by the present inventors, when the height H₁₀₅ of the first banks 105 is 1.5 μm or 2.0 μm, layer thickness uniformity of the organic light-emitting layer 107 cannot be ensured.

### (ii) Thickness of Second Banks 115

The thickness H₁₁₅ of the second banks 115 is preferably within a range that satisfies the following equation.

H₁₁₅≦0.8 μm [Math 6]

As determined by the present inventors, despite some occurrence of uncovered portions of the second banks 115 when the thickness H₁₁₅ of the second banks 115 was the upper limit (0.80 μm), the uncovered portions did not affect light-emitting properties. Thus, the upper limit of the thickness H₁₁₅ of the second banks 115 is 0.8 μm.

Further, when the thickness H₁₁₅ of the second banks 115 was 0.50 μm, portions of the second banks 115 not covered by ink did not occur, which is preferable. In contrast, when the thickness H₁₁₅ of the second banks exceeded the upper limit (0.80 μm) and had a value of 1.0 μm, occurrence of uncovered portions of the second banks 115 was high, which was unacceptable in view of light-emitting properties.

### 7. Method of Manufacturing the Display Panel 10

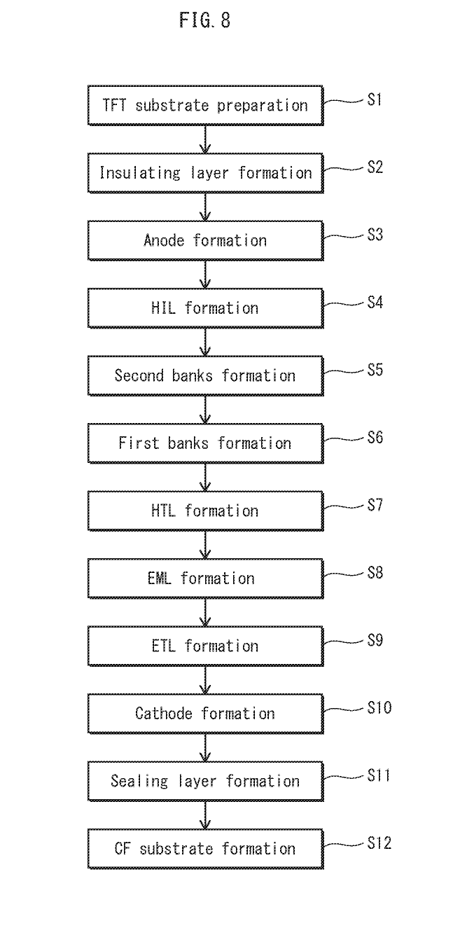

A method of manufacturing the display panel 10 pertaining to the present embodiment is described with reference to FIG. 8.

As illustrated in FIG. 8, in manufacture of the display panel 10, first, a TFT substrate is prepared (step S1). The TFT substrate is the TFT layer 101 formed on the substrate 100, and is manufactured by using known techniques.

Subsequently, the insulating layer 102 is formed on the TFT substrate (step S2). The insulating layer 102 may be formed by, for example, applying an organic material onto a passivation layer of the TFT layer 101, and, after the organic material is planarized and hardened, opening the contact hole 102a (see FIG. 4) in the insulating layer 102.

Subsequently, the anode 103 and the hole injection layer (HIL) 104 are formed above the insulating layer 102 (step S3, step S4). The anode 103 may be formed, for example, by patterning by using photolithography and etching after formation of a metal layer by using a method such as sputtering or vacuum deposition. As illustrated in FIG. 4, the anode 103 is connected to an upper electrode of the TFT layer 101 (electrode connected to source or drain) via the contact hole 102a opened in the insulating layer 102.

The hole injection layer 104 may be formed, for example, by patterning of each sub-pixel 10a, 10b, 10b, 10c₁, 10c₂ by using photolithography and etching after formation of a layer comprising a metal oxide (for example, tungsten oxide WOx) by sputtering.

Subsequently, the second banks 115 are formed (step S5). The second banks 115 may be formed, for example, by spin coating of a material (for example, a photosensitive acrylic resin material) used to form the second banks 115 to form a layer comprising the material. Subsequently, the layer is patterned by exposure and development, and baked.

In a similar way, the first banks 105 are formed (step S6). The first banks 105 may be formed, for example, by using a method such as spin coating or roll coating to form a layer of a material (for example, a photosensitive resin material) used to form the first banks 105 to completely cover an area above the substrate 100 including the second banks 115, then performing patterning by exposure and development, then baking.

Although not specified in FIG. 8, UV irradiation processing and baking processing is performed with respect to the first banks 105 and the second banks 115. The UV irradiation processing is performed, for example, for 150 s to 200 s, and the baking processing is performed, for example, for 10 min to 20 min at 150° C. to 230° C.

Subsequently, the hole transport layer (HTL) 106 is formed in a groove portion (opening 105a in FIG. 6) defined by two adjacent ones of the first banks 105, as illustrated in FIG. 5 (step S7). The hole transport layer 106 may be formed, for example, by applying ink containing material for forming the hole transport layer 106 to the groove portion defined by the adjacent ones of the first banks 105 by a printing method such as inkjet printing, and drying the ink.

In a similar way, the organic light-emitting layer (EML) 107 and the electron transport layer (ETL) 108 are formed, in this order, in the groove portion defined by the adjacent ones of the first banks 105 (step S8, step S9). In formation of the organic light-emitting layer 107 and the electron transport layer 108, as in the formation of the hole transport layer 106 described above, ink containing corresponding material is applied, then dried.

Subsequently, the cathode 109 and the sealing layer 110 are formed in this order, covering the hole transport layer 108 and the first banks 105 (step S10, step S11). The cathode 109 and the sealing layer 110 may be formed, for example, by methods such as sputtering and chemical vapor deposition (CVD).

Subsequently, the display panel 10 is completed by attachment of a CF substrate comprising the color filter layer 113, the black matrix layer 112, and the substrate 114 (step S12). This attachment may be performed by application and hardening of a resin material between the CF substrate and the sealing layer 110. The resin layer 111 is formed by the hardening of the resin material that is applied between the CF substrate and the sealing layer 110.

### [Modification]

Configuration of the organic EL display device and display panel pertaining to a modification is described below.

The schematic configuration of the organic EL display device according to this modification is similar to the embodiment above, but a difference from the embodiment above is in configuration of a portion between the second banks, the hole transport layer, and the first banks in the display panel. Specifically, according to the display panel pertaining to this modification, at least a portion (preferably all) of a surface portion of the second banks is covered by an inorganic layer. The hole transport layer and the first banks are formed layered on the second banks with the inorganic layer disposed therebetween.

Here, the inorganic layer comprises an inorganic material that is preferably an insulating material. As specific examples, a silicon oxide, silicon nitride, or silicon oxynitride may be used.

In the display panel pertaining to this modification, diffusion, during formation of the first banks, of fluorine included in the second banks to a surface portion of the hole injection layer can be suppressed by covering at least a portion of the surface portion of the second banks with the inorganic layer.

For example, in a case in which an organic layer for forming the first banks is formed after formation of the second banks that comprise an organic material, organic material of the second banks contacts organic material of the organic layer, and a portion of fluorine components included in the second banks may diffuse into the surface portion of the hole injection layer.

However, by covering at least a portion of the surface portion of the second banks with the inorganic layer, as in this modification, diffusion of fluorine components when the first banks are formed from at least the portion covered by the inorganic layer can be suppressed.

As above, material of the inorganic layer is preferably an insulating material, but in a case in which only a portion of the surface portion of the second banks is covered with the inorganic layer, an electrically conductive material may be used.

Further, thickness of the inorganic layer is not particularly limited as long as diffusion of fluorine components can be suppressed, and may be 1 nm to 10 nm, for example.

### [Other Matters]

The embodiment and modification above describe an organic EL display panel as an example of an organic light-emitting device, but the technology pertaining to the present disclosure is not limited to this example. For example, the same effects can be achieved when the technology of the present disclosure is applied to organic EL lighting.

Further, according to the embodiment above, an active matrix display panel is described, but the technology pertaining to the present disclosure is not limited to this example. For example, the same effects can be achieved when the technology of the present disclosure is applied to a passive matrix display panel.

Further, according to the embodiment above, the fluorine concentration Df₁₁₅ of the surface portion 115f of each of the second banks 115 is less than 7.5% of the fluorine concentration Df₁₀₅ of the surface portion 105f of each of the first banks 105, but the same effects can be achieved when this ratio of fluorine concentration is less than 10%.

Further, as illustrated in FIG. 2, according to the embodiment above, one pixel comprises a combination of three sub-pixels 10a, 10b, 10c in a rectangular shape in plan view, but the technology pertaining to the present disclosure is not limited to this example. For example, planar shape of sub-pixels may be that of a triangle, hexagon, octagon, etc., having an overall honeycomb appearance. The number of sub-pixels for one pixel may be four, and may be a greater number than four. In such a case, the sub-pixels for a pixel may all emit different color light from each other, or a portion of the sub-pixels may emit the same color light as each other.

Further, a particular method of changing fluorine concentration of the surface portion 105f of each of the first banks 105 and the surface portion 115f of each of the second banks 115 is not described in the embodiment above, but may be implemented by changing fluorine concentration of materials, by changing irradiation strength or irradiation time of UV light after bank formation, etc.

Further, according to the embodiment above, the first banks 105 and the second banks 115 are formed by using organic material, but the first banks 105, the second banks 115, or the first banks 105 and the second banks 115 may be formed by using inorganic material. In this case, as long as the fluorine concentration of surface portions thereof satisfy the relationship described above, the effects described above can be achieved.

Further, according to the embodiment and modification above, the hole injection layer 104 is formed below the first banks 105 and the second banks 115 as a layer comprising inorganic material, but in a case in which the hole injection layer 104 is formed as an organic layer, the hole injection layer may be formed in the groove defined by adjacent ones of the first banks 105. In this case, layers below the second banks 115 become edge portions of the anode 103 and exposed portions of the insulating layer 102.

Further, according to the embodiment above, a top-emission type of the display panel 10 is used as an example, but the same effects can be achieved even when the technology of the present disclosure is applied to a bottom-emission type of display panel.

The technology pertaining to the present disclosure is useful when implementing an organic light-emitting device that has high light emitting properties.

Although the technology pertaining to the present disclosure has been fully described by way of examples with reference to the accompanying drawings, it is to be noted that various changes and modifications will be apparent to those skilled in the art. Therefore, unless such changes and modifications depart from the scope of the present disclosure, they should be construed as being included therein.

1. An organic light-emitting device comprising:
a substrate;
light emitters in a two-dimensional arrangement along a surface of the substrate; and
banks that define the light emitters, wherein
each of the light emitters comprises:
a first electrode disposed above the substrate;
an organic functional layer disposed above the first electrode, the organic functional layer including at least an organic light-emitting layer; and
a second electrode disposed on the organic functional layer, wherein
the banks comprise:
first banks that are each elongated in a first direction along the surface of the substrate and are arranged to be separated from each other in a second direction along the surface of the substrate that is perpendicular to the first direction; and
second banks that are each elongated in the second direction and are arranged to be separated from each other in the first direction, wherein
the first banks and the second banks each comprise an insulating material, at least a surface portion of each of the first banks that faces the organic functional layer contains fluorine, at least a surface portion of each of the second banks that faces the organic functional layer contains fluorine, the first banks are above the second banks at each intersection between the first banks and the second banks, and
fluorine concentration of the surface portion of each of the second banks is less than 10% of fluorine concentration of the surface portion of each of the first banks.

2. The organic light-emitting device of claim 1, wherein
the fluorine concentration of the surface portion of each of the second banks is less than 7.5% of the fluorine concentration of the surface portion of each of the first banks.

3. The organic light-emitting device of claim 1, wherein
in each of the light emitters, a charge injection layer is disposed between the first electrode and the organic functional layer, the charge injection layer being in contact with the organic functional layer, and
the fluorine concentration of the surface portion of each of the second banks is less than 400% of fluorine concentration of a surface portion of the charge injection layer that faces the organic functional layer.

4. The organic light-emitting device of claim 1, wherein
each of the second banks comprises an organic material, and
an inorganic layer is disposed between at least a portion of each shared boundary between the second banks, the organic functional layer, and the first banks, the inorganic layer being comprised of an inorganic material and in contact with each of the second banks, the organic functional layer, and each of the first banks.

5. The organic light-emitting device of claim 4, wherein
the inorganic layer comprises silicon oxide, silicon nitride, or silicon oxynitride.

6. The organic light-emitting device of claim 1, wherein
thickness of each of the second banks is 0.80 μm or less.

7. The organic light-emitting device of claim 6, wherein
height of each of the first banks is from 0.50 μm to 1.1 μm higher than each of the second banks.

8. The organic light-emitting device of claim 6, wherein
the first electrode, at a portion of a peripheral region of each respective one of the light emitters, has a flat region along a plane parallel to the surface of the substrate,
each of the second banks is above the flat region of corresponding ones of the first electrode, and
the thickness of each of the second banks is defined as thickness of a portion of each of the second banks above the flat region of corresponding ones of the first electrode.

9. An organic display device comprising:
a display panel; and
control/drive circuitry connected to the display panel, wherein
the display panel comprises:
a substrate;
light emitters in a two-dimensional arrangement along a surface of the substrate; and
banks that define the light emitters, wherein
each of the light emitters comprises:
a first electrode disposed above the substrate;
an organic functional layer disposed above the first electrode, the organic functional layer including at least an organic light-emitting layer; and
a second electrode disposed on the organic functional layer, wherein
the banks comprise:
first banks that are each elongated in a first direction along the surface of the substrate and are arranged to be separated from each other in a second direction along the surface of the substrate that is perpendicular to the first direction; and
second banks that are each elongated in the second direction and are arranged to be separated from each other in the first direction, wherein
the first banks and the second banks each comprise an insulating material, at least a surface portion of each of the first banks that faces the organic functional layer contains fluorine, at least a surface portion of each of the second banks that faces the organic functional layer contains fluorine, the first banks are above the second banks at each intersection between the first banks and the second banks, and
fluorine concentration of the surface portion of each of the second banks is less than 10% of fluorine concentration of the surface portion of each of the first banks.
